(19) United States
(12) Patent Application Publication
(10) Pub. No.: US 2012/0297755 A1
(43) Pub. Date: Nov. 29, 2012

(54) MODULE, ASSEMBLY WITH MODULE, THERMOELECTRIC GENERATOR UNIT AND EXHAUST GAS CONDUIT DEVICE WITH GENERATOR UNIT

(76) Inventors: Martin Adldinger, Holzheim (DE); Wolfgang Hahnl, Grimma (DE); Marco Ranalli, Augsburg (DE); Christian Vitek, Boos (DE); Robin Willats, Columbus, IN (US)

(21) Appl. No.: 13/516,815

(22) PCT Filed: Dec. 17, 2010
(86) PCT No.: PCT/EP2010/007758

§ 371 Date: Aug. 14, 2012

(30) Foreign Application Priority Data
Dec. 17, 2009 (DE) 10 2009 058 550.8

(51) Int. Cl. H01L 35/32; H01L 35/34; F01N 5/02

(52) U.S. Cl. 60/320; 136/224; 136/208; 136/201

(57) ABSTRACT

A thermoelectric module (10) has a plurality of series-connected thermoelectric elements which are arranged between a first module housing plate defining a high-temperature side and a second module housing plate defining a low-temperature side, wherein laterally beside the thermoelectric elements and towards the end faces of the module housing plates at least one elastic compensating element is provided, which exerts a lateral holding force on the thermoelectric elements and extends from one inner side of the opposed module housing plates to the other. Such thermoelectric module (10) is contained in a thermoelectric generator unit (100), with a generator housing (102) in which at least one elastic compensating element (20) and at least one thermoelectric module (10) are accommodated, wherein the generator housing (102) exerts a pretension on the thermoelectric module (10) via the elastic compensating element (20).

This invention relates to a thermoelectric module, in particular for a thermoelectric generator unit, which among other things can be used in an exhaust gas conduit device, in particular for an internal combustion engine.

Thermoelectric modules are devices which convert thermal energy into electric energy. They include thermoelectric elements working on the basis of the Seebeck effect or the Peltier effect, in which due to the used specific material pairing of different metals or different semiconductor materials as well as the temperature difference existing over the thermoelectric element an electric voltage is generated. In this way it is possible to utilize for example the thermal energy of the exhaust gas stream for generating electric energy.

The different coefficients of thermal expansion of the individual components of a thermoelectric module must be compensated, just like a uniform, sufficient, but not excessive pressing force between the individual components must be ensured, in order to ensure an optimum heat transfer from the hot exhaust gas to the thermoelectric elements.

It is the object of the invention to propose a simple and inexpensive solution for the construction of a thermoelectric module.

This is achieved in a thermoelectric module with a plurality of series-connected thermoelectric elements which are arranged between a module housing plate defining a high-temperature side and a module housing plate defining a low-temperature side, wherein laterally beside the thermoelectric elements and towards the end faces of the module housing plates at least one elastic compensating element, in particular a mat, is provided, which exerts a lateral holding force on the thermoelectric elements and extends from one inner side of the opposed module housing plates to the other.

The elastic compensating element preferably is fabricated from a large-surface thin part, in particular a mat, such as a known mounting mat as it is used when installing catalyst substrates, or a fiber mat of a suitable material. The fiber mat for example can be a nonwoven fabric, a knitted fabric, a mesh, but also a woven fabric, for example of a steel wire.

The group of thermoelectric elements arranged one beside the other is accommodated between the laterally arranged elastic compensating elements. The same on the one hand provide the pretension which holds the unit of thermoelectric elements and possibly interposed heat-conducting elements in close thermal contact, but on the other hand offer enough flexibility, in order to compensate different thermal expansions. The holding force exerted by the compensating elements is directed parallel to the module housing plates. In this way, a compact thermoelectric module can be created with little material effort, which has a high life expectancy.

Preferably, the module housing plates are part of a module housing which completely encloses the thermoelectric elements and the elastic compensating element. Hence, a completely encapsulated module can be created, in which damage and soiling of the thermoelectric elements are prevented. It is merely necessary to lead the electric connection cables out of the module housing.

Useful thermoelectric elements advantageously include plate-shaped elements, whose flat side e.g. substantially extends at right angles to the module housing plates. The temperature difference can extend vertical to the module housing plates or, when using suitable heat-conducting elements, parallel thereto. The heat-conducting elements transport the heat from the module housing plates to the flat sides of the elements extending vertical thereto.

If the temperature difference should extend vertical to the module housing plates, the thermoelectric elements preferably are arranged such that the end faces of adjacent p- or n-conducting elements are connected via an electrically and thermally conducting bridge which is in contact with the inside of the module housing plates. Between the individual thermoelectric elements, electrically insulating packings then preferably are provided.

The invention also relates to an assembly of a thermoelectric module and a heat exchanger element.

A good heat transfer between the hot/cold medium and the high- or low-temperature side of the thermoelectric module is essential, in order to optimally utilize the thermal energy of the medium.

It is also an object of the invention to propose an improvement in this point.

In an assembly comprising a thermoelectric module with a high-temperature side and a low-temperature side and at least one heat exchanger element arranged on the high-temperature side and/or the low-temperature side of the thermal module it therefore is provided that the heat exchanger element is connected with the thermoelectric module by gluing. An adhesive bond, in particular a large- or full-surface bond, between the high-temperature or low-temperature side of the thermoelectric module and the heat exchanger element creates a very good thermally conductive connection over the entire surface of the two components. In addition, the adhesive bond ensures a secure hold and makes further mechanical fastening elements superfluous. The manufacturing time and costs of the assembly also are reduced thereby.

Such assembly for example can be used in a thermoelectric module as described above or in an exhaust gas conduit system as will yet be explained below, but also independent of the embodiments described here generally in any heat exchanger in which part of the thermal energy is to be converted into electric energy. The construction is suitable both for heat exchangers operating with fluids, but also for those which operate with a gaseous medium.

The adhesive preferably is a glass or ceramic adhesive, wherein for example in particular for the connection with the high-temperature side a glass solder, a glass-containing adhesive or a ceramic adhesive on the basis of aluminum oxide, aluminum oxynitride or boron nitride are used. Such adhesives ensure a secure connection also at high temperatures for a long time.

The adhesive also can be a two-component adhesive, with such adhesive preferably being used for the connection on the low-temperature side. For example, a combination of a silane-terminated polymer and a synthetic resin can be used, as it is commercially available under the name Collane RS 8500.

Preferably, the heat exchanger element includes protruding ribs, as it is known from conventional heat exchangers. Such construction is suitable both for arrangement on the high-temperature side and for arrangement on the low-temperature side.

The heat exchanger element for example can consist of a folded metal foil. This allows a fast and inexpensive manufacture.

The metal foil also can adopt the role of the module housing, so that separate module housing plates between the thermoelectric elements and the heat exchanger element can be omitted.

The ribs preferably are formed by folds in the metal foil. Advantageously, flat pieces are formed between the ribs, which are in contact with the thermoelectric module. Via the flat pieces the heat transfer from the heat exchanger element to the thermoelectric module substantially is effected.

In one possible embodiment, the adhesive only is provided between the flat pieces and the thermoelectric module. The foil portions which form the ribs, however, are not fixed to each other.

The adhesive also can be provided on the entire metal foil, which offers the advantage that for manufacturing purposes the metal foil can completely be coated with adhesive, before the metal foil is folded and the heat exchanger element is attached to the thermoelectric module.

It is also possible to provide the adhesive on the flat pieces only in the region of the electrical connection of adjacent thermoelectric elements of the thermoelectric module, i.e. in the region of the bridges. The thermoelectric elements and the packings arranged between the same have different coefficients of thermal expansion, and the different changes in length can be compensated by this arrangement.

The invention also relates to a thermoelectric generator unit, in particular for coupling to an exhaust gas conduit of an internal combustion engine. By means of the thermoelectric generator unit, electric energy can be obtained from the thermal energy of the exhaust gas, which for example is usable for the electric loads in the vehicle.

A rather good heat coupling between the hot medium and the thermoelectric module used in the generator unit is essential to achieve a high efficiency.

Furthermore, it is the object of the invention to propose a simple and inexpensive construction for a thermoelectric generator unit.

In a thermoelectric generator unit, in particular for coupling to an exhaust gas conduit of an internal combustion engine, a generator housing is provided in accordance with the invention, in which at least one elastic compensating element, in particular a mat, and at least one thermoelectric module are accommodated, with the thermoelectric module having a high-temperature side and a low-temperature side and a plurality of thermoelectric elements combined to a unit, wherein the generator housing exerts a pretension on the thermoelectric module via the elastic compensating element, in order to clamp the same in the generator housing. Via the clamping force, air gaps are reduced or eliminated and a secure hold of the modules is achieved.

It is possible to use one of the thermoelectric modules described above as thermoelectric module. One of the above-described assemblies just as well can be used in the thermoelectric generator unit.

In the present application, the elastic compensating element in particular is a large-surface, thin component for all applications and for example can be formed by a mounting mat or a fiber mat, as they have already been described.

The elastic compensating element can exert a contact pressure on a flat side of the plate-shaped thermoelectric module and for example can rest against the same. It causes a sufficient pretension with different manufacturing tolerances of all parts installed and a force balance, so that the thermoelectric module always is secure even with changing temperatures, but is held in the generator housing without too large a force acting on the same. Hence, an optimum heat transfer always is ensured, and the thermoelectric module is safe from mechanical overloads. Preferably, the thermal energy of the exhaust gas is utilized directly, in that the thermoelectric generator unit is formed such that it is inserted into the exhaust gas stream and is traversed by the same. It would, however, also be possible to only guide part of the exhaust gas stream through the thermoelectric generator unit, if necessary, or to heat up another medium which flows through the generator unit via the exhaust gas.

The generator housing can seal the thermoelectric generator unit except for inflow and outflow openings for exhaust gas or another hot medium.

Advantageously, the fixation of the thermoelectric module and of the other components is purely effected by clamping in the generator housing. Alternatively, for example, clamping and at the same time an adhesive connection can be realized.

In a preferred embodiment, there is provided at least one first channel element traversed by a hot medium, which in the generator housing is in contact with the high-temperature side of the thermoelectric module, and/or at least one second channel element traversed by a cooling medium, which is in contact with the low-temperature side of the thermoelectric module.

The channel elements act as fluid channel and as heat exchanger at the same time, by absorbing or releasing thermal energy from the fluid or from the thermoelectric module.

The one or more channel elements can loosely be mounted in the housing and be clamped in the housing only by the action of the elastic compensating element and be clamped against the thermoelectric module. As hot medium, the exhaust gas itself or a gaseous or liquid medium heated by the exhaust gas can be used. As cooling medium, a cooling fluid such as water or air can be employed.

The elastic compensating element for example can be arranged between at least one channel element and the inside of the generator housing.

It is possible to accommodate two thermoelectric modules in the generator housing, between which a first channel element or a second channel element is arranged and on whose opposite sides the second channel element or the first channel element each is arranged. An assembly of three or even more thermoelectric modules with corresponding channel elements is of course also possible. For each thermoelectric module a separate first channel element and a separate second channel element for hot medium or cooling medium can each be provided, or a first or second channel element each can supply two adjacent thermoelectric modules.

In the first case it is recommendable to arrange the channel elements conducting the hot medium so as to face each other, just like the channel elements conducting the cooling medium. This results in a mirror-symmetrical construction each for two adjoining assemblies.

In the second case, the elastic compensating element preferably is arranged between two of the identical channel elements, and the second channel elements, which conduct the cooling medium, rest against the insides of the housing, in order to be able to release heat to the outside. The arrangement of hot and cold side could of course also be vice versa.

Both with regard to the clamping effect and with regard to the compensating effect of the elastic compensating element, the same can be arranged at various points in the generator housing. Both an arrangement between an inside of the generator housing and other components of the thermoelectric generator unit and an arrangement between components of the thermoelectric generator unit away from the generator housing satisfies the function provided in accordance with the invention.

In a preferred embodiment, at least one of the channel elements includes ribs, which improves a heat transfer.

As channel element, a heat exchanger element described above can also be used here. The hot medium or the cooling medium then is guided along the ribs as in known heat exchangers.

The channel element can be folded from a metal foil, as is described above for the heat exchanger element.

It is also possible to form the channel element from a sheet metal with ribs attached thereto analogous to known heat exchangers.

In a preferred embodiment, the generator housing has a round, cylindrical shape and the channel elements form circular segments as seen in cross-section and between themselves accommodate the at least one thermoelectric module. The thermoelectric module of course is arranged on the flat sides of the channel elements.

A simple and inexpensive thermoelectric generator unit can also be realized in that the first and/or the second channel element is formed as tubular body with a substantially cylindrical peripheral wall with ribs arranged in the channel interior enclosed by the peripheral wall.

For filling up the channel interior, the ribs preferably are formed with different lengths, when the channel interior differs from the rectangular shape, and preferably extend from a flat to an arc-shaped wall. In principle it is possible to divide the entire cross-section of the generator housing, unless it is filled up by the thermoelectric module narrow in cross-section, into individual narrow channels by the ribs of the channel elements, so that large contact surfaces with the channel elements are created for the flowing hot and cold media.

The formation of the flow channels for the hot and cold media preferably is achieved by the channel elements themselves.

The ribs can be arranged one beside the other in parallel or in a grid-like manner. A grid-like arrangement has the advantage of a high mechanical stability. In both cases, the ribs only form a low flow resistance. The distance of the ribs can be constant over the cross-section of the channel element or vary in adaptation to the respective flow conditions.

Advantageously, the channel elements are formed as prefabricated parts.

The channel elements for example can simply be fabricated in one piece from a ceramic material or a metal by an extrusion method. To a large extent, they can be designed freely in terms of size and shape and thus can easily be adapted to the respective geometrical conditions. In particular, the cross-sectional shape and the number and distance of the ribs can be varied in a simple way.

In particular, it is possible in this case to provide the channel element traversed by exhaust gas with a catalytic coating.

Wrapped with the flat elastic compensating element, the assembly of thermoelectric module and channel element can be clamped in the housing.

In another preferred embodiment, at least one channel element is formed with a flat, in particular rectangular cross-section. Here, the channel element preferably is a tube.

In a preferred embodiment, at least two assemblies each of a thermoelectric module, a first channel element arranged on the high-temperature side and a second channel element arranged on the low-temperature side are provided, which are separated from each other by the elastic compensating element and are clamped in the generator housing pretensioned by the compensating element. The assemblies are arranged mirror-symmetrically, wherein the first channel elements conducting the hot medium are directed towards each other and the second channel elements conducting the cooling medium are arranged towards the outside of the housing.

On the outside of the generator housing cooling ribs can be provided, in order to release heat to the surroundings and thus keep the temperature difference over the thermoelectric module as large as possible.

Preferably, a plurality of thermoelectric modules are arranged one beside the other for forming a plate-shaped layer, so that thermoelectric generator units with any dimension can be realized.

The invention also relates to a method for manufacturing a thermoelectric generator unit as it has been described above.

It is the object to show how such thermoelectric generator unit can be fabricated in a simple and inexpensive way.

In accordance with the invention, a generator housing is provided. The channel elements and the at least one thermoelectric module are wrapped with the elastic compensating element for forming an assembly, and the assembly is inserted into the housing, so that the assembly enclosed by the housing is clamped in the housing. The elastic compensating element surrounds the one or more thermoelectric modules and the channel elements and lies between the inside of the wall of the generator housing and the channel elements. In this way, the assembly is clamped in the generator housing at each point of the circumference with uniform force, and it is also prevented that for example due to thermal expansion too high a force acts on a part of the assembly, since the elastic compensating element absorbs and distributes the forces.

When the generator housing is tubular, inserting the assembly into the generator housing can be effected by stuffing the assembly into the housing.

According to another possible method, a housing shell is provided, and the assembly is wrapped with the housing shell, so that a closed housing is formed. This method is a so-called canning method, also referred to as wrapping method.

It is also possible to push the assembly into the generator housing and subsequently plastically deform the same from the outside to the inside (shrinking). In this case, the generator housing is fabricated with a slight oversize.

In all methods, a calibrating step can be provided, in which the housing diameter is varied and in particular reduced.

All the aforementioned methods ensure that the assembly of channel elements, thermoelectric module and elastic compensating element is safely held in the generator housing by clamping with a sufficient, but not excessive force.

It is also possible to collect data on the assembly to be installed, which permit statements on the volume, the elasticity or strength of the assembly or of individual components thereof, and with reference to these data individually manufacture the generator housing, in order to produce a desired individual clamping force.

Further advantages and features of the invention can be taken from the following description of several embodiments with reference to the attached drawings, in which:

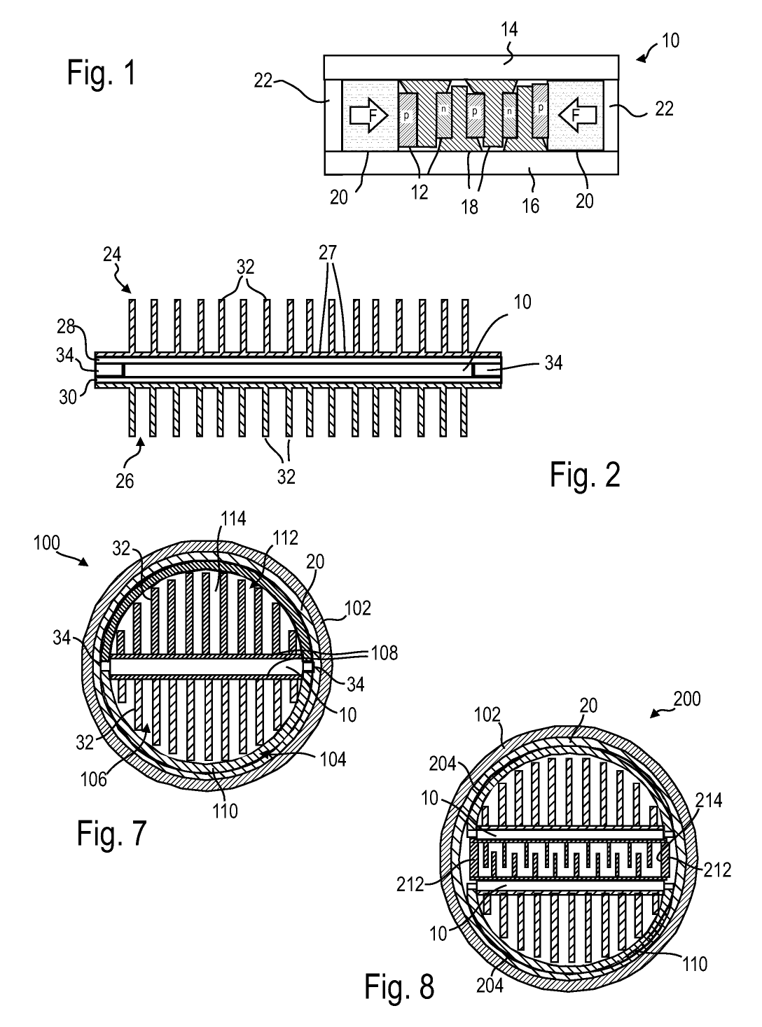

FIG. 1 shows a schematic sectional view of a thermoelectric module according to the invention;

FIG. 2 shows a schematic sectional view of an assembly according to the invention with a thermoelectric module and two heat exchanger elements;

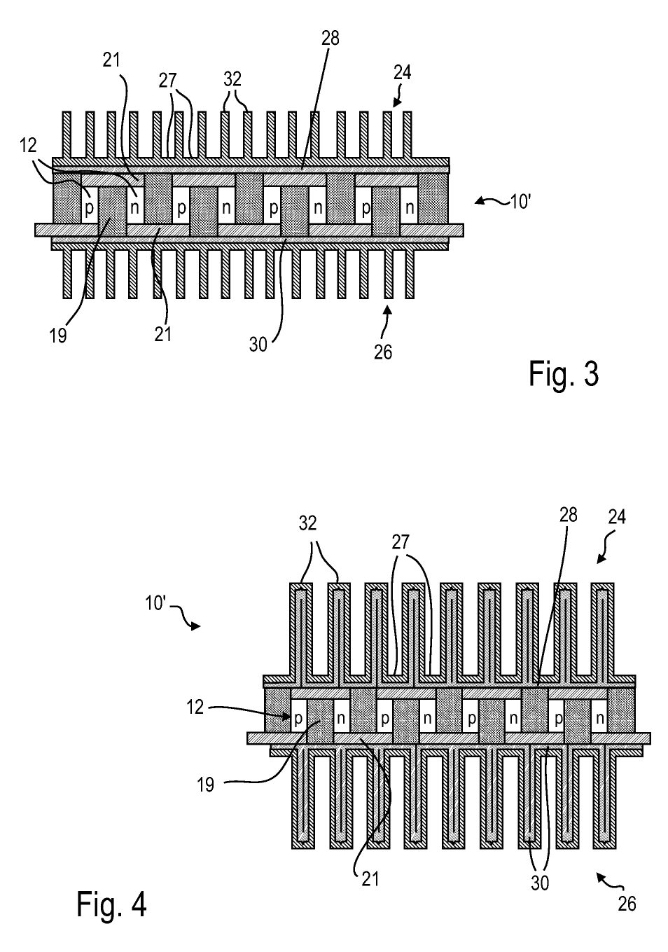

FIGS. 3 to 6 show various variants of an assembly of a thermoelectric module and two heat exchanger elements according to the invention;

FIG. 7 shows a schematic sectional view of a thermoelectric generator unit of the invention according to a first embodiment;

FIG. 8 shows a schematic sectional view of a thermoelectric generator unit of the invention according to a second embodiment;

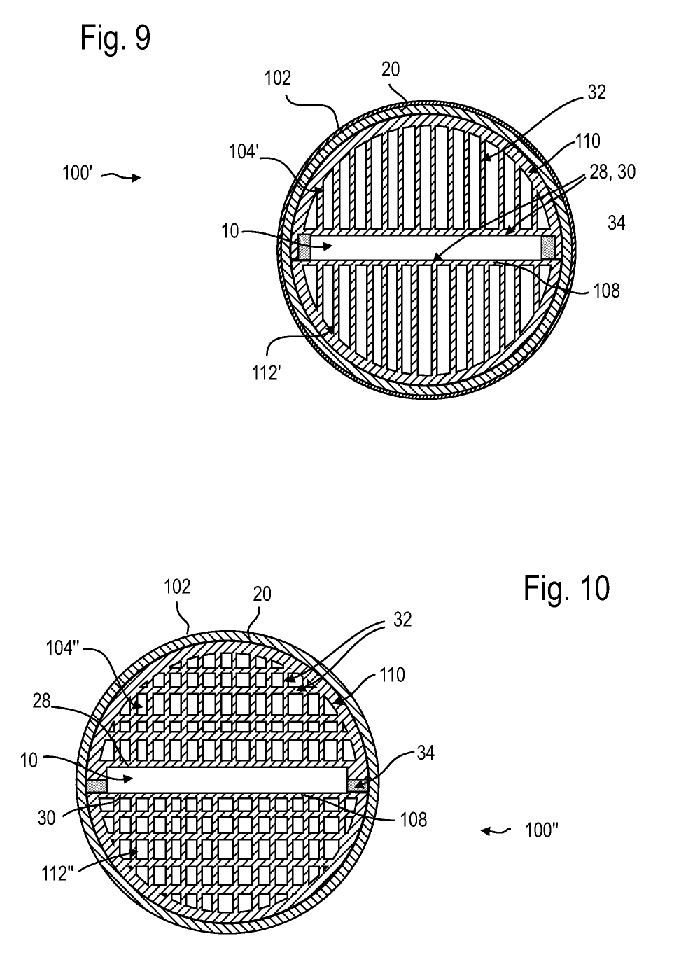

FIGS. 9 and 10 show two further embodiments of a thermoelectric generator unit according to the invention;

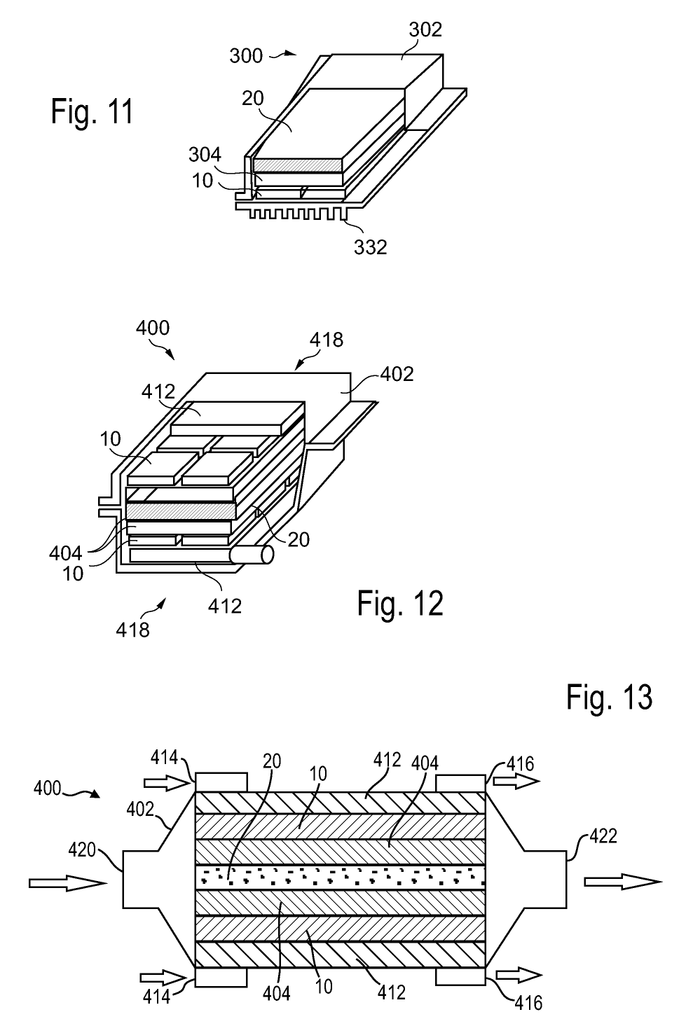

FIG. 11 shows a schematic perspective view of a thermoelectric generator unit of the invention according to a third embodiment, wherein the housing is shown partly cut open;

FIG. 12 shows a schematic perspective view of a thermoelectric generator unit of the invention according to a fourth embodiment, wherein the housing is shown partly cut open;

FIG. 13 shows a schematic sectional view of an exhaust gas conduit device according to the invention with a thermoelectric generator unit from FIG. 6;

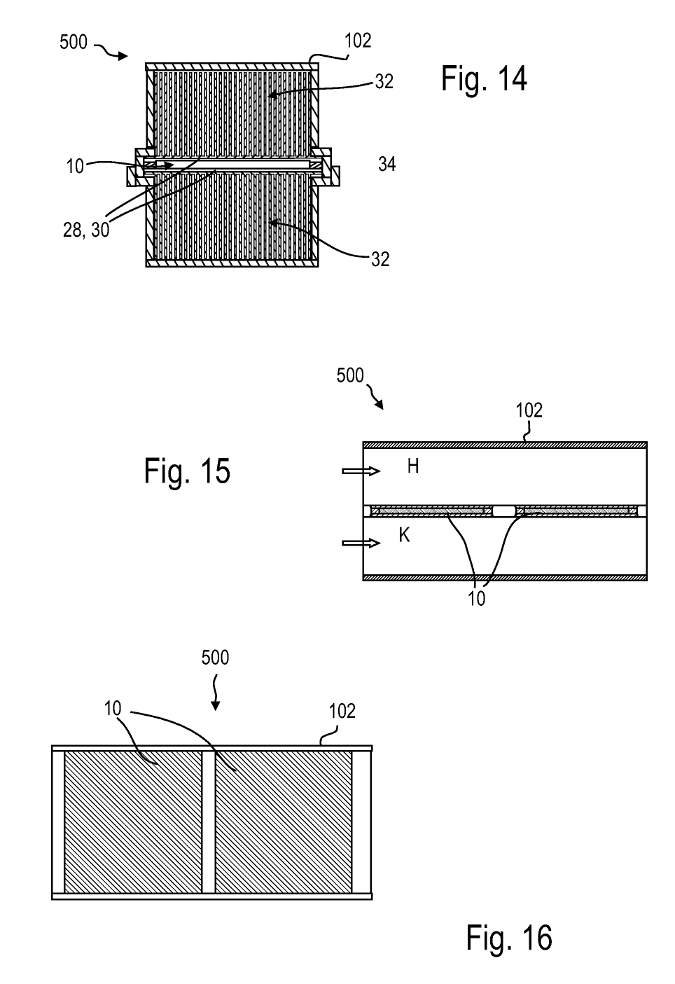

FIGS. 14 to 16 show a various views of a thermoelectric generator unit of the invention according to a further embodiment;

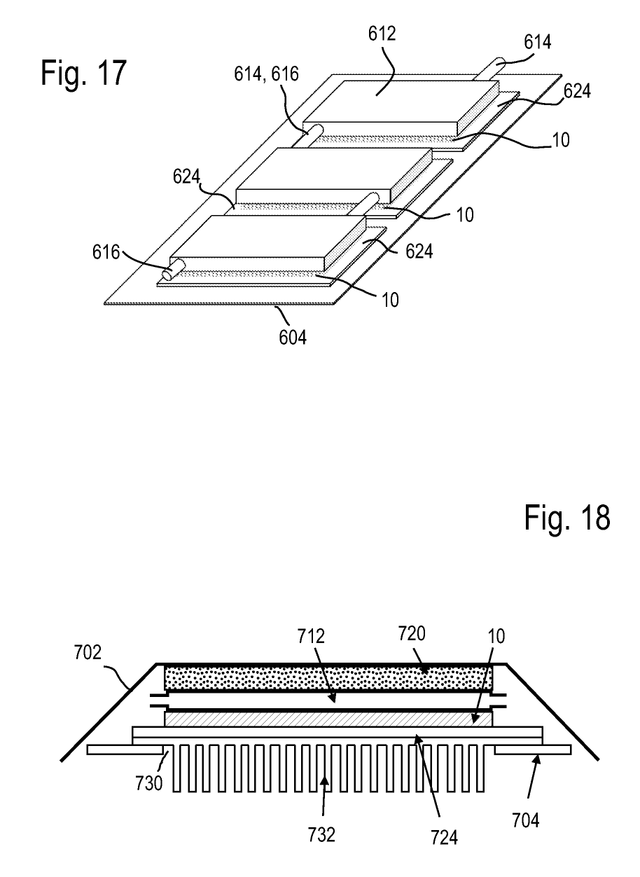

FIG. 17 shows a portion of a thermoelectric generator unit of the invention according to a further embodiment;

FIG. 18 shows a schematic sectional view of a portion of a thermoelectric generator unit of the invention according to a further embodiment; and

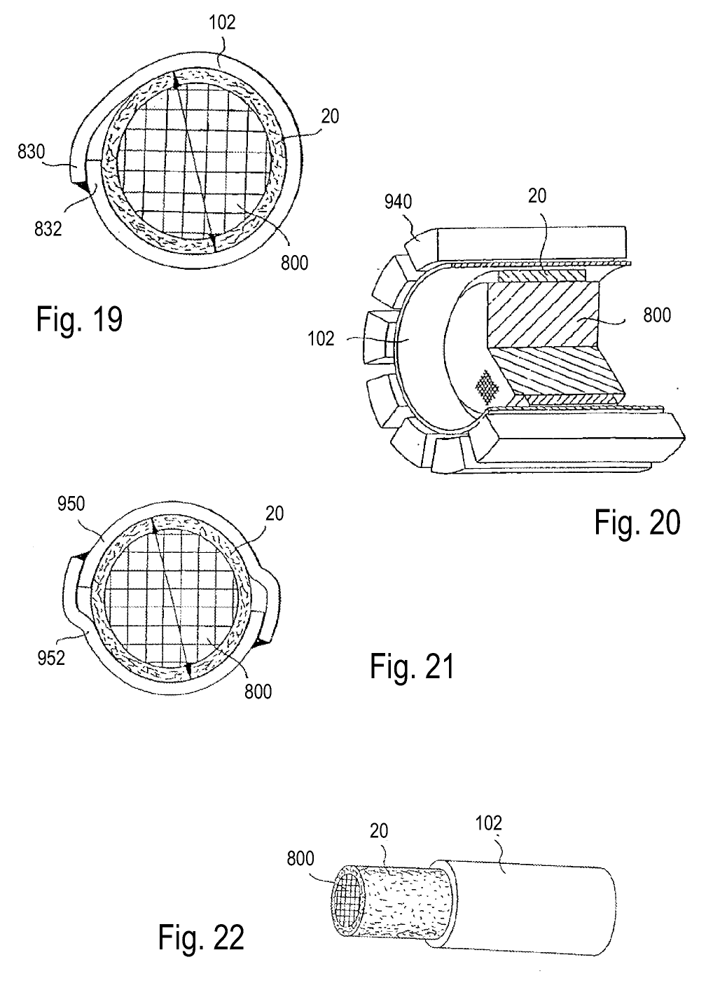

FIGS. 19 to 22 show several canning methods usable according to the invention.

FIG. 1 shows a thermoelectric module 10, with a plurality of individual thermoelectric elements 12 arranged one beside the other and electrically connected in series, which are made of known suitable semiconductor materials or metals. The individual thermoelectric elements 12 are plate-shaped and arranged on edge one beside the other, with p- and n-conducting elements alternating, like in known modules.

The elements 12 are arranged vertical to a first module housing plate 14 and a parallel second module housing plate 16. In this case, the first module housing plate 14 defines a low-temperature side of the thermoelectric module 10 and the second module housing plate 16 defines a high-temperature side of the thermoelectric module 10.

In this example, the module housing plates consist of a ceramic insulator which has a rather good thermal conductivity.

Between the individual thermoelectric elements 12, there are arranged heat-conducting elements 18 of a material with good thermal conductivity such as copper, which are T-shaped and conduct heat from the high-temperature side to the thermoelectric elements 12 or dissipate heat from the thermoelectric elements 12 to the low-temperature side. This is schematically shown in FIG. 1. The heat-conducting elements 18 of course are arranged such that no thermal bridges are formed between the module housing plates 14, 16. The vertically extending legs of the heat-conducting elements 18 lie between an n-conducting and a p-conducting element. In the illustrated example, the temperature gradient extends parallel to the module housing plates 14, 16, transverse to the longitudinal extension of the elements 12. For this arrangement, a construction known per se can be chosen.

Alternatively, however, arrangements are conceivable, in which the temperature difference exists vertical to the module housing plates 14, 16 across the thermoelectric elements 12. Such arrangement is chosen in the thermoelectric modules which are shown in FIGS. 3 to 6. The individual thermoelectric elements 12 are arranged on edge one beside the other, with p- and n-conducting elements alternating. Between the individual thermoelectric elements 12, a packing 19 of an electrically insulating material each is provided. On the end faces, adjacent thermoelectric elements 12 are connected via an electrically and thermally conductive bridge 21 whose surface is in contact with the high- or low-temperature side of the thermoelectric module 10′ and by which on the one hand the electric contact of the thermoelectric elements 12 among each other and on the other hand the heat transfer to the thermoelectric elements 12 is achieved.

Laterally beside the group of the thermoelectric elements 12 and the heat-conducting elements 18 towards the end faces of the module housing plates 14, 16 an elastic compensating element 20 each is arranged between the module housing plates 14, 16 (optionally in the modules 10′ shown in FIGS. 3 to 6). The two elastic compensating elements 20 here rest against the end faces of the group of thermoelectric elements 12 and against the insides of the end plates 22 of the module housing, wherein the module housing is formed by the module housing plates 14, 16 and the end plates 22. The end plates 22 are made of an electrically and thermally rather poorly conducting material, in order to avoid both electric short-circuits and thermal bridges between the module housing plates 14, 16. The elastic compensating elements 20 exert a laterally directed force F on the thermoelectric elements 12, as is illustrated by the arrows in FIG. 1.

In this example, the elastic compensating elements 20 are formed by pieces of mounting or fiber mats, as they are used for example as clamping and compensating elements for the fixation of catalyst substrates. The mat for example can consist of a mesh, a knitted fabric or a non-woven fabric, e.g. of a steel wire. The thermoelectric elements 12 are laterally pretensioned and clamped by the mat and possibly can creep in the case of temperature expansions. In terms of height, the dimensions of the compensating element 20 correspond to the distance of the module housing plates 14, 16, whereas the width approximately corresponds to the width of one or more of the thermoelectric elements 12. In its length the compensating element 20 can extend over the entire group of the thermoelectric elements 12.

The dimensions of the module housing and the elastic compensating elements 20 are chosen such that no further fastening elements or clamping elements are necessary for the thermoelectric elements 12 in the module housing.

The thermoelectric module 10 is completely sealed against its surroundings and thus protected against environmental influences. Merely electrical terminals (not shown) extend out of the housing.

The thermoelectric module 10 is plate-shaped, with both module housing plates 14, 16 having a distinctly larger surface extension than the distance between the two module housing plates 14. 16.

A plurality of thermoelectric modules 10 can be attached to each other in one plane to form a plate-shaped layer which substantially can have any dimension. This is shown for example in FIG. 12. In the following, no conceptual distinction is made between an individual module and a plate-shaped layer of thermoelectric modules, which actually is composed of a plurality of individual modules. Both are designated with the reference numerals 10 and 10′, respectively. For all embodiments, any number of modules can also be positioned one beside the other, in order to form a kind of layer.

FIG. 2 shows an assembly with a thermoelectric module 10 and a first heat exchanger element 24 attached to its high-temperature side and a second heat exchanger element 26 attached to the low-temperature side.

The thermoelectric module 10 can be a thermoelectric module described above or another suitable thermoelectric module, for example a module 10′ like in the embodiments of FIGS. 3 to 6.

Both heat exchanger elements 24, 26 are bonded to the housing sides, in this case the module housing plates 14, 16 of the thermoelectric module 10, over a large area. The used adhesive should withstand the temperatures to which the assembly is exposed and should have a rather good thermal conductivity.

The adhesive between the low-temperature side of the thermoelectric module 10 and the first heat exchanger element 24 here consists of a layer 28 of a suitable two-component adhesive. For example, there can be used a combination of a silane-terminated polymer and a synthetic resin, as it is commercially available under the trade name Collano RS 8500.

On the high-temperature side of the thermoelectric module 10 the adhesive layer 30 between the module housing and the second heat exchanger element 26 in this example is formed by a glass or ceramic adhesive. Suitable adhesives here for example include glass-based adhesives, glass solder or ceramic adhesives on the basis of aluminum oxide, aluminum oxynitride or boron nitride.

Each of the two heat exchanger elements 24, 26 for example consists of a metal foil which is folded such that there is formed a plurality of flat pieces 27 interposed vertically thereto and individual ribs 32 located parallel to each other and protruding vertical to the thermoelectric module 10. The hot or cold medium flows between these ribs 32. The flat pieces 27 are directed to the housing side of the thermoelectric module 10 and bonded to the same. The foil portions, which form the ribs, can rest flat against each other and optionally be bonded to each other, so that the flat pieces 27 substantially form a continuous surface.

FIGS. 3 to 6 show various variants of such an assembly. In all cases, separate module housing plates are omitted in the thermoelectric module 10′. This function is performed by the heat exchanger elements 24, 26. As already described above, the same each consist of a one-piece metal foil, which is folded such that ribs 32 with interposed flat pieces 27 are obtained. The heat exchanger elements 24, 26 are directly bonded to the high-temperature or low-temperature side of the thermoelectric module 10′.

In the embodiment shown in FIG. 3, an adhesive layer 28, 30 is provided only in the region of the flat pieces 27, whereas the metal foil is not bonded in the region of the ribs 32.

In the variant of FIG. 4, by contrast, the adhesive layer 28, 30 is provided on the entire metal foil, so that the two side faces of the individual ribs 32 are also each bonded to each other. Before folding the metal foil, the respective adhesive here is applied to the foil over a large area, e.g. by spraying, and thereafter the foil is folded and adhered to the high- or low-temperature side of the thermoelectric module 10′.

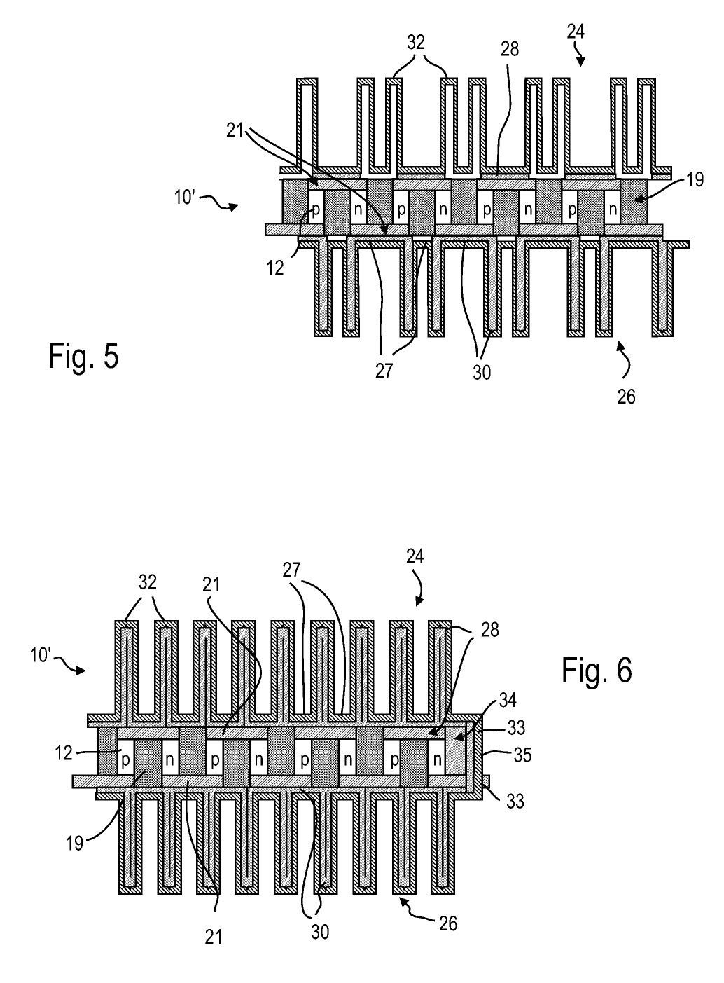

FIG. 5 shows a variant in which the adhesive layer 28, 30 in the region of the flat pieces 27 only is provided over the bridges 21 between the thermoelectric elements 12, in order to account for the different coefficients of thermal expansion of the thermoelectric elements 12 and the packings 19. The side faces of the ribs 32 can be bonded to each other (FIG. 5 below) or not (FIG. 5 above). The distances of the ribs 2 and hence the width of the flat pieces 27 vary in dependence on the length of the bridges 21 and the packings 19, respectively.

The heat exchanger elements 24, 26 also can be formed like in the case of the variant in FIG. 6, so that they fully enclose the thermoelectric module 10′ and thus not only satisfy the function of the module housing plates, but of a complete housing. For this purpose, the two heat exchanger elements 24, 26 for example are designed with free edge portions 33 and placed around the module 10′ such that the edge portions 33 cover the narrow sides of the module 10′ and there are welded to each other at a welding seam 35.

It would also be possible to use conventional heat sinks with ribs for the heat exchanger elements 24, 26, for example a metal sheet might be provided with further sheet metal pieces soldered or welded thereto, which form the ribs 32, or the heat exchanger elements 24, 26 might be fabricated as castings or extruded parts with ribs formed thereon.

On the narrow sides, the thermoelectric module 10 can be surrounded by a narrow stabilizing element 34, for example also in the form of an elastic compensating element, in order to protect the module against mechanical influences. FIGS. 7 to 12 show various variants of thermoelectric generator units, which each include one or more thermoelectric modules 10 which can be identical with the thermoelectric module 10 described above. Other thermoelectric modules can, however, also be used.

All thermoelectric generator units shown are suitable for being inserted into the exhaust gas stream of an exhaust gas conduit as exhaust gas conduit devices, so that they are directly traversed by the hot exhaust gas. It would, however, also be possible to arrange them parallel to an exhaust gas conduit, so that they are traversed by the exhaust gas as needed or transmit the heat from the exhaust gas to a medium which then flows through the thermoelectric generator units.

It is possible to arrange only one or a plurality of thermoelectric generator units in the exhaust gas system.

In the embodiments shown in FIGS. 7 and 8 the thermoelectric generator unit 100 or 200 includes a cylindrical, tubular, elongated generator housing 102.

In the embodiment as shown in FIG. 7, a thermoelectric module 10 is arranged along the diameter of the generator housing 102 parallel to the same, with the width of the thermoelectric module 10 being chosen slightly smaller than the diameter of the generator housing 102.

On the high-temperature side of the thermoelectric module 10 a first channel element 104 is arranged, which forms a first, substantially closed channel 106 which is traversed by hot exhaust gas or another hot medium.

The first channel element 104 for example consists of two parts which are put together such that they form a fluid-tight channel 106. In its construction, the first part is similar to the above-described heat exchanger elements 24, 26. On a flat base surface 108 it is connected face to face with the high-temperature side of the thermoelectric module 10, for example bonded as described above, and includes vertically protruding ribs 32 which extend into the channel 106 and provide a large heat transfer surface for the hot medium flowing therethrough.

The ribs 32 are adapted to the tube diameter and vary in their length, so that the entire cross-section available is subdivided by the ribs 32. As above for the heat exchanger element 24, 26, this portion of the channel element 104 can be folded from a metal foil.

The second part is a bowl-shaped wall element 110 which terminates with the base surface 108 and is connected with the same such that the fluid-tight channel 106 is formed.

The first channel element 104′ also can be fabricated in one piece as cast or extruded part from a suitable, e.g. thermally conductive, ceramic, sintered, material or from a suitable material such as stainless steel, cast iron or aluminum, as is shown in FIGS. 9 and 10. In this case, the ribs 32 are formed integrally with the flat base surface 108 and the wall element 110. As material, the same material can be employed as for the module housing plates 14, 16.

As ceramic material, for example a ceramic with an Al₂O₃ content of more than 80% is used. Such a ceramic has a thermal conductivity comparable to stainless steel (about 10-30 W/mK). An aluminum nitride with a thermal conductivity of more than 100 W/mK or a silicon nitride (15-45 W/mK) can also be used. When the channel elements are made of an electrically insulating ceramic material, they also protect the thermoelectric module against short-circuits.

In an alternative embodiment, the channel element 104″ is provided with ribs 32 arranged in a grid-like manner in its channel interior, which here cross each other at right angles. Ribs 32 and wall parts are integrally fabricated with each other. The distance of the ribs 32 and hence the cross-section of the channels formed by the same can be constant, but can also vary.

On its inside, the channel element 104′ optionally is coated with a catalytically active substance for converting the noxious substances contained in the exhaust gas.

On the low-temperature side of the thermoelectric module 10 a second channel element 112, 112′ or 112″ is arranged, which in its construction here is substantially identical to the first channel element 104, 104′ or 104″. The second channel element 112 defines a second channel 114, which is traversed by a cooling medium such as water, another cooling fluid or air, and with its base surface is connected with the low-temperature side of the thermoelectric module 10.

The two bowl-shaped wall elements 110 of the first and the second channel element 104, 112 abut against each other at the stabilizing elements 34 of the thermoelectric module 10, so that here a force balance can take place.

The flat base surfaces 108 can perform the function of the module housing plates 14, 16, so that the same can be omitted, in order to achieve a more direct heat transfer.

Between the channel elements 104, 112 and the high- or low-temperature side of the thermoelectric module 10 a functional layer, for example in the form of a thermally conductive paste or one of the adhesives described already (in the Figures designated with the reference numerals 28 and 30) can be provided for improvement of the heat transfer.

The two channel elements 104, 112 and the interposed thermoelectric module 10 are completely wrapped with an elastic compensating element 20 in the form of a thin flat mat, for example a mounting mat or a fiber mat as it has been described above.

In a uniform thickness around the entire circumference the elastic compensating element 20 for example lies between the inner wall of the generator housing 102 and the outside of the wall elements 110 of the channel elements 104, 112. By means of the slightly compressed elastic compensating element 20, a firm clamping of the assembly of elastic compensating element 20, channel elements 104, 112 and thermoelectric module 10 is achieved in the generator housing 102. In addition, the elastic compensating element 20 absorbs forces which result from different coefficients of thermal expansion and thus prevents an excessive force acting on the channel elements 104, 112 and above all on the thermoelectric module 10.

In principle, the embodiment shown in FIG. 8 corresponds to the one just described. In the following, only the differences will be explained. In the embodiment shown in FIG. 8, two thermoelectric modules 10 are arranged with a distance to each other parallel to the extension of the generator housing 102.

Their high-temperature sides point away from each other to the outside. On each high-temperature side a first channel element 204 is mounted, so that it points to the inner wall of the generator housing 102. The first channel elements 204 have the same basic construction as the first channel elements 104 of the embodiment as shown in FIG. 7.

The two low-temperature sides of the thermoelectric modules 10 are facing each other, and on the low-temperature sides two second channel elements 212 are mounted, which form a common coolant channel 214 in the middle of the generator housing 102. Each of the second channel elements 212 substantially has a construction like one of the heat exchanger elements 24, 26 described above. The ribs 32 of the two second channel elements 212 alternately engage in each other, but are formed only so long that there is still left a distance to the base surface of the respective other channel element 212. On the long sides, the two second channel elements 212 are connected with each other such that the channel 214 is fluid-tight.

Like in the embodiment described in FIG. 7, the assembly of the two thermoelectric modules and the channel elements is wrapped with an elastic compensating element 20 which lies between the components and the inside of the generator housing 102. All components are held in the generator housing 102 only by clamping.

For manufacturing the thermoelectric generator units 100, 200 several methods are presented. In each case, all thermoelectric modules 10 and channel elements 104, 112 or 204, 212 to be used first are brought into the desired arrangement, which they should adopt later on in the generator housing 102. Then, these components are completely wrapped with the elastic compensating element 20 on their circumference.

Inserting this prefabricated assembly into the housing can be effected in different ways.

According to one method, the assembly is stuffed in axial direction into the cylindrical generator housing 102 already closed in circumferential direction.

According to another possible method, the generator housing 102 is closed only on insertion of the assembly and initially is present as a bent housing shell. Then, the assembly is wrapped with the housing shell, so that a closed housing is formed. This method is a so-called wrapping method.

It is also possible to push the assembly into the generator housing 102 and subsequently plastically deform the same from the outside to the inside. In this case, the generator housing 102 is fabricated with a slight oversize.

According to a further alternative, the housing can be formed of two half shells which are closed around the assembly by deforming their edges or which are partly put into each other and soldered or welded to each other.

Optionally, a calibration step can be provided in addition, in which the housing diameter is varied and in particular reduced, in order to achieve the desired clamping force between the assembly and the inside of the generator housing 102.

It is also possible to collect data on the assembly to be installed, which permit statements on the volume, the elasticity or strength of the assembly or of individual components thereof, and with reference to these data individually manufacture the generator housing 102, in order to produce a desired clamping force.

The channel elements 104-104″, 108-108″ also can have another cross-section, e.g. a rectangular shape. The generator housing 102 then has a correspondingly adapted shape. If the channel elements 104-104″, 108-108″ are fabricated from a metal, the compensating element 20 can be omitted and the generator housing 102 can be welded or soldered.

FIGS. 11 and 12 describe two further embodiments of thermoelectric generator units. In these two embodiments, a layered structure of plate-shaped thermoelectric modules 10 and plate-shaped channel elements or compensating elements is chosen.

In the embodiment of a thermoelectric generator unit 300 as shown in FIG. 11, a thermoelectric module 10 is arranged in a generator housing 302 with a rectangular cross-section in contact with the lower side of the generator housing 302 as seen in FIG. 5, so that a low-temperature side is in contact with the inside of the generator housing 302. On the high-temperature side of the thermoelectric module 10 a first channel element 304 is arranged in face-to-face contact with the high-temperature side.

In this embodiment, the first channel element 304 is designed as tube with a rectangular cross-section. The width of the channel element 304 is chosen such that it approximately corresponds to the width of the generator housing 302. In this case, the cross-section of the channel element 304 has no ribs. On the channel element 304 and between the channel element 304 and the inside of the generator housing 302 an elastic compensating element 20 is arranged in the form of a flat mat. As also previously, this can be e.g. a mounting mat or a fiber mat.

The thermoelectric module 10, the channel element 304 and the compensating element 20 completely fill the cross-section of the generator housing 302 and are clamped in the generator housing 302 by means of the elastic compensating element 20, as has already been described for the other embodiments.

The generator housing 302 has a rectangular cross-section, so that it positively surrounds the assembly of thermoelectric module 10, channel element 304 and elastic compensating element 20.

On the bottom side of the generator housing 302 as shown in FIG. 11 conventional cooling ribs 332 are formed in contact with the low-temperature side of the thermoelectric module 10, via which heat is dissipated to the surroundings. A separate coolant conduit is not provided in this case, but might be present.

In the embodiment shown in FIG. 12, two thermoelectric modules 10 are arranged with a distance to each other in the generator housing 402, which is designed analogous to the generator housing 302, with their low-temperature sides being directed to the outside and their high-temperature sides being directed to the inside. In each of the thermoelectric modules 10 a second channel element 412 is arranged on the low-temperature side and a first channel element 404 is arranged on the high-temperature side.

Both the first and the second channel elements 404, 412 here are formed e.g. as flat tubes with rectangular cross-section, like the channel element 304 in the embodiment described in FIG. 11. The first channel elements 404 are traversed by hot medium, while the second channel elements 412 are traversed by a cooling medium.

The two assemblies of the thermoelectric module 10 and the channel elements 404, 412 arranged on the high-temperature side and the low-temperature side, respectively, are spaced from each other by an elastic compensating element 20 in the form of a mat. In the plane extending into the drawing plane in FIG. 12, all components substantially have the same dimensions.

In the generator housing 402, the individual components are stacked one above the other in direct contact, as is schematically shown in FIG. 13. The two coolant-carrying second channel elements 412 are located in direct contact with the wall of the generator housing 402.

For each of the second channel elements 412 the generator housing 402 each includes an inlet 414 and an outlet 416 for the cooling medium. The cooling medium circuit is designed in a known way and will not be illustrated here in more detail.

At the end faces 418, the thermoelectric generator unit 400 includes an inflow opening 420 and an outflow opening 422, which are only shown in FIG. 7. Through these openings, exhaust gas or hot medium flows into the thermoelectric generator unit 400, more exactly into the first channel element 404, and again leaves the same.

All components preferably are held in the generator housing 402 only by clamping via the elastic compensating element 20, without further additional mechanical holding elements or adhesive bonds being necessary.

As shown, the generator housing 402 can enclose all components, but might also be designed in the form of individual separate clamps.

FIGS. 14 to 16 show a thermoelectric generator unit 500 which contains one of the assemblies as described above. A generator housing 102 of a sheet metal encloses the assembly and is positively fixed at the thermoelectric module 10, so that only minimal forces act on the ribs 32. The thermoelectric module divides the generator housing 102 in two channels H, K, wherein one of the channels is traversed by a hot medium and the other one by a cold medium.

In the illustrated case, two thermoelectric modules 10 are arranged one behind the other in the generator housing 102 (see FIGS. 15 and 16).

FIG. 17 shows a further embodiment of a thermoelectric generator unit. On a flat wall of a channel element 604 conducting hot gas a plurality of thermoelectric modules 10 are arranged axially one behind the other.

On its high-temperature side directed towards the channel element 604, each of the modules 10 is connected with its own heat exchanger 624.

On the low-temperature side, a channel element 612 is arranged on each of the thermoelectric modules 10, whose base area approximately corresponds to that of the module 10. The individual channel elements 612 are linearly connected by conduit portions, which each form an inlet 614 and an outlet 616 for the cooling medium flowing through the channel elements 612. Inlet 614 and outlet 616 of each channel element 612 are arranged offset on opposite end faces, in order to ensure a uniform flow.

In the embodiment of a thermoelectric generator unit as shown in FIG. 18, a plurality of thermoelectric modules 10 are arranged on the flat wall of a channel element 704 traversed by hot gas.

In the wall of the channel element 704, an opening 730 each is formed below the module 10. On its high-temperature side, the module 10 is connected with a heat exchanger element 724, e.g. by gluing. Edge regions of the module 10 or of the heat exchanger element 724 are connected with the edge of the opening 730 such that the opening 730 is sealed gas-tight with respect to the channel element 704.

Portions of the heat exchanger element 724, here a number of ribs 732, protrude into the hot gas stream and transport the heat to the high-temperature side of the thermoelectric module 10.

On the low-temperature side of the module 10 a channel element 712 is provided, which is traversed by a cooling medium. Here for example the same arrangement can be chosen as it has been described in connection with FIG. 17.

The channel element 704 can be formed with a polygonal cross-section, wherein thermoelectric modules 10 can be provided on each side. It can, however, also be designed rectangular.

The assembly of channel element 704, thermoelectric modules 10, heat exchanger elements 724 and channel elements 712 is wrapped with an elastic compensating element 720, here in the form of a mounting mat, and surrounded by a generator housing 702. Mounting the assembly in the housing 702 is effected as described above. Preferably, the edge 740 of the module 10 rests against the edge of the opening 730 on the outside, so that the pressing force of the compensating element 720 supports the sealing effect at the edges.

All features of the individual devices, methods, assemblies and embodiments can be combined, separately realized or replaced for each other as desired according to the discretion of the skilled person. The features mentioned in the following sentences and paragraphs need not necessarily be combined with each other, but represent advantageous examples.

In particular, the use of one of the described thermoelectric modules is independent of a use in one of the described thermoelectric generator units, and the same can of course also be used for applications other than exhaust gas conduit devices.

In FIGS. 19 to 22 the canning methods usable according to the invention are explained.

In the so-called wrapping as shown in FIG. 19, the compensating element 20 is placed around the simplified assembly 800 of the channel elements and thermoelectric modules, and the unit thus obtained is installed in its custom-made outer housing 102. For this purpose, the prefabricated outer housing 102 is slightly spread and the unit is laterally pushed into the outer housing 102. The outer housing 102 is closed under pressure and/or path control by pushing the overlapping edges 830, 832 over each other to such an extent that the dimensions of the outer housing 102 obtained correspond to previously determined values. The closing process is effected with reference to suitable parameters previously determined in a controller and adjusted to the individual assembly 800 or the compensating element 20. Subsequently, the overlapping edges are joined, e.g. welded, folded, soldered or glued.

Beside wrapping the outer housing 102, mounting can also be effected by so-called calibrating. A corresponding calibration device is shown in FIG. 20. The same comprises numerous circular-segment-shaped, radially movable jaws 940, which can close to form a ring. Into the interior of the working space circumscribed by the jaws 940 the circular cylindrical, tubular outer housing 102 is inserted, into which the unit is pushed axially. The jaws 940 subsequently are radially moved to the inside, using the values previously determined in the controller with respect to the geometry of the outer housing 102. This means that the desired dimensions of the outer housing 102 previously determined by the controller are achieved by a path-controlled movement of the jaws 940 by simultaneous plastic deformation of the previously already circumferentially closed outer housing 102 pre-formed with a correspondingly larger diameter. Of course, corresponding calibration methods are also possible for non-circular-cylindrical assemblies 800.

Instead of the jaws 940 shown in FIG. 20, calibrating can also be effected by means of rollers which are laterally pressed against the outer housing with the insert provided therein by the predetermined path of movement and are rotated. In this connection, a so-called pressing also is possible, in which the outer housing 102 with the unit arranged therein is relatively moved against an individual roller by the predetermined path of movement, and subsequently a relative rotation is effected between the roller and the outer housing together with the unit, so that the roller circumferentially presses into the outer housing 102 and plastically deforms the same to the inside.

The method shown in FIG. 21 operates with two or more shells 950, 952, which are pushed into each other. Here as well, the shells 950, 952 are pushed into each other under path or pressure control, until the inside dimensions correspond to the determined dimensions. The shells 950, 952 then are e.g. welded to each other, folded or soldered. Of course, the shells 950, 952 also can already be formed to the desired final dimensions in advance.

FIG. 22 symbolizes the so-called stuffing. In the measuring device, the desired dimensions of the outer housing 102 are determined. Then, a cylindrical outer housing 102 is manufactured with the desired target diameter and the corresponding shape. For example, this is effected by rolling. Subsequently, the unit is axially stuffed into the selected outer housing 102. Of course, corresponding funnel-shaped aids are provided here.

1. A thermoelectric module with a plurality of series-connected thermoelectric elements which are arranged between a first module housing plate defining a high-temperature side and a second module housing plate defining a low-temperature side, wherein laterally beside the thermoelectric elements and towards the end faces of the module housing plates at least one elastic compensating element, in particular a mat, is provided, which exerts a lateral holding force on the thermoelectric elements and which extends from one inner side of the opposed module housing plates to the other.

2. The thermoelectric module according to claim 1, wherein the module housing plates are part of a module housing which fully encloses the thermoelectric elements and the elastic compensating element.

3. The thermoelectric module according to claim 1, wherein the thermoelectric elements are plate-shaped parts which with their flat side substantially extend at right angles to the module housing plates.

4. An assembly comprising:
a thermoelectric module with a plurality of series-connected thermoelectric elements which are arranged between a first module housing plate defining a high-temperature side and a second module housing plate defining a low-temperature side, wherein laterally beside the thermoelectric elements and towards the end faces of the module housing plates at least one elastic compensating element, in particular a mat, is provided, which exerts a lateral holding force on the thermoelectric elements and which extends from one inner side of the opposed module housing plates to the other, with a first module housing plate defining a high-temperature side and a second module housing plate defining a low-temperature side, and
at least one heat exchanger element arranged on the high-temperature side and/or the low-temperature side of the thermoelectric module,
wherein the heat exchanger element is connected with the thermoelectric module by gluing.

5. The assembly according to claim 4, wherein the adhesive is a glass solder, a glass-containing adhesive, a ceramic adhesive or a two-component adhesive.

6. The assembly according to claim 4, wherein the heat exchanger element includes protruding ribs.

7. The assembly according to claim 4, wherein the heat exchanger element consists is comprised of a folded metal foil.

8. The assembly according to claim 7, wherein the ribs are formed in the metal foil by folding and between the ribs flat pieces are formed, which are in contact with the thermoelectric module.

9. The assembly according to claim 8, wherein the adhesive only is present between the flat pieces and the thermoelectric module.

10. The assembly according to claim 8, wherein the adhesive is present on the entire metal foil.

11. The assembly according to claim 8, wherein the adhesive is provided on the flat pieces only in the region of points of contact of thermoelectric elements of the thermoelectric module with the high- or low-temperature side.

12. A thermoelectric generator unit, in particular for coupling to an exhaust gas conduit of an internal combustion engine, with a generator housing in which at least one elastic compensating element in the form of a mat as well as at least one thermoelectric module are accommodated, wherein the thermoelectric module has a high-temperature side and a low-temperature side and comprises a plurality of thermoelectric elements combined to a unit and preferably is a thermoelectric module with a plurality of series-connected thermoelectric elements which are arranged between a first module housing plate defining a high-temperature side and a second module housing plate defining a low-temperature side, wherein laterally beside the thermoelectric elements and towards the end faces of the module housing plates at least one elastic compensating element, in particular a mat, is provided, which exerts a lateral holding force on the thermoelectric elements and which extends from one inner side of the opposed module housing plates to the other, wherein the generator housing exerts a pretension on the thermoelectric module via the elastic compensating element, in order to clamp the same in the generator housing.

13. The thermoelectric generator unit, according to claim 12 and for coupling to an exhaust gas conduit of an internal combustion engine, with at least one thermoelectric module which has a high-temperature and a low-temperature side and a plurality of thermoelectric elements combined to a unit, wherein there is provided at least one first channel element traversed by a hot medium, wherein, in the generator housing, the first channel element being in contact with the high-temperature side of the thermoelectric module, and/or at least one second channel element traversed by a cooling medium, which is in contact with the low-temperature side of the thermoelectric module, wherein the first and/or the second channel element is formed as tubular body with a substantially cylindrical peripheral wall with ribs arranged in the channel interior enclosed by the peripheral wall.

14. The thermoelectric generator unit according to claim 13, wherein the ribs are arranged in parallel one beside the other or in a grid-like manner.

15. The thermoelectric generator unit according to claim 12, wherein there is provided at least one first channel element traversed by a hot medium, the first channel element, in the generator housing being in contact with the high-temperature side of the thermoelectric module, and/or at least one second channel element traversed by a cooling medium, which is in contact with the low-temperature side of the thermoelectric module.

16. The thermoelectric generator unit according to claim 13, wherein that between at least one channel element and the inside of the generator housing the elastic compensating element is arranged.

17. The thermoelectric generator unit according to claim 13, wherein two thermoelectric modules are accommodated in the generator housing, between which a first channel element or a second channel element is arranged and on whose opposite sides the second channel element and the first channel element is arranged.

18. The thermoelectric generator unit according to claim 13, wherein at least one of the channel elements includes ribs.

19. The thermoelectric generator unit according to claim 13, wherein the channel element is folded from a metal foil.

20. The thermoelectric generator unit according to claim 13, wherein the channel element is formed from a sheet metal with ribs attached thereto.

21. The thermoelectric generator unit according to claim 13, wherein the channel element is integrally made from a ceramic material or a metal, in particular by extrusion.

22. The thermoelectric generator unit according to claim 13, wherein the generator housing has a round, cylindrical shape and the channel elements form circular segments as seen in cross-section and accommodate the at least one thermoelectric module between themselves.

23. The thermoelectric generator unit according to claim 18, wherein the channel elements include ribs which have different lengths for filling the channel interior and preferably extend from a flat wall to an arc-shaped wall.

24. The thermoelectric generator unit according to claim 13, wherein the assembly/assemblies of thermoelectric module and channel element(s) wrapped with the flat elastic compensating element is clamped in the generator housing.

25. The thermoelectric generator unit according to claim 13, wherein the channel elements are formed as prefabricated parts.

26. The thermoelectric generator unit according to claim 13, wherein at least one channel element has a flat, in particular rectangular cross-section.

27. The thermoelectric generator unit according to claim 13, wherein at least two assemblies each of a thermoelectric module, a first channel element arranged on the high-temperature side and a second channel element arranged on the low-temperature side are provided, which are separated from each other by the elastic compensating element and are clamped in the generator housing pretensioned by the elastic compensating element.

28. The thermoelectric generator unit according to claim 13, wherein on the outside of the generator housing cooling ribs are provided.

29. The thermoelectric generator unit according to claim 13, wherein a plurality of thermoelectric modules are arranged one beside the other for forming a plate-shaped layer.

30. The thermoelectric generator unit according to claim 13, wherein the thermoelectric module is part of an assembly.

31. An exhaust gas conduit device, in particular for an internal combustion engine, with an exhaust gas conduit and at least one thermoelectric generator unit for coupling to an exhaust gas conduit of an internal combustion engine, with a generator housing in which at least one elastic compensating element in the form of a mat as well as at least one thermoelectric module are accommodated, wherein the thermoelectric module has a high-temperature side and a low-temperature side and comprises a plurality of thermoelectric elements combined to a unit and preferably is a thermoelectric module with a plurality of series-connected thermoelectric elements which are arranged between a first module housing plate defining a high-temperature side and a second module housing plate defining a low-temperature side, wherein laterally beside the thermoelectric elements and towards the end faces of the module housing plates at least one elastic compensating element, in particular a mat, is provided, which exerts a lateral holding force on the thermoelectric elements and which extends from one inner side of the opposed module housing plates to the other, wherein the generator housing exerts a pretension on the thermoelectric module via the elastic compensating element, in order to clamp the same in the generator housing, which is arranged in the exhaust gas conduit and is traversed by exhaust gas.

32. A method for manufacturing a thermoelectric generator unit for coupling to an exhaust gas conduit of an internal combustion engine, with at least one thermoelectric module which has a high-temperature and a low-temperature side and a plurality of thermoelectric elements combined to a unit, wherein there is provided at least one first channel element traversed by a hot medium, wherein, in the generator housing, the first channel element being in contact with the high-temperature side of the thermoelectric module, and/or at least one second channel element traversed by a cooling medium, which is in contact with the low-temperature side of the thermoelectric module, wherein the first and/or the second channel element is formed as tubular body with a substantially cylindrical peripheral wall with ribs arranged in the channel interior enclosed by the peripheral wall, with the following steps:
providing a generator housing,
wrapping the channel elements and the at least one thermoelectric module with the elastic compensating element for forming an assembly, and
inserting the assembly into the generator housing, so that the assembly is enclosed by the generator housing and clamped in the generator housing.

33. The method according to claim 32, wherein the generator housing is tubular and inserting the assembly into the generator housing is effected by stuffing the assembly into the generator housing.

34. The method according to claim 32, wherein housing shell is provided and the assembly is wrapped with the housing shell, so that a closed generator housing is formed.

35. The method according to claim 32 wherein the assembly is pushed into the generator housing and the same subsequently is plastically deformed from the outside to the inside.

36. The method according to claim 32, wherein a calibrating step is provided, in which the housing diameter is varied, in particular reduced.

37. The method according to claim 32, wherein data are collected on the assembly to be installed, which data permit statements on the volume, the elasticity or strength of the assembly or of individual components thereof, and that the generator housing is manufactured individually with reference to these data, in order to produce a desired clamping force.
